(19) United States
(12) Patent Application Publication
(10) Pub. No.: US 2026/0100427 A1
(43) Pub. Date: Apr. 9, 2026

(54) BATTERY MANAGEMENT MODULE AND BATTERY PACK COMPRISING THE SAME

(71) Applicant: SAMSUNG SDI CO., LTD., Yongin-Si Gyeonggi-do (KR)

(72) Inventors: Pyungkap KIM, Yongin-Si (KR); Hyunsoo KIM, Yongin-Si (KR)

(21) Appl. No.: 19/211,623

(22) Filed: May 19, 2025

(30) Foreign Application Priority Data
Oct. 7, 2024 (KR) 10-2024-0135958

(51) Int. Cl. H01M 10/42; G01R 31/327; G07C 5/08; H01M 10/48; H02J 7/00

(52) U.S. Cl. CPC H01M 10/425; G01R 31/3278; H01M 10/48; G07C 5/0808; H01M 2010/4271; H01M 2220/20; H02J 7/52

(57) ABSTRACT

A battery management module includes: at least one battery cell; a first relay connected to a first terminal of the at least one battery cell; a second relay connected to a second terminal of the at least one battery cell; and a microcontroller to: receive a first voltage value of a first voltage across both ends of the first relay; receive a second voltage value of a second voltage across both ends of the second relay; and generate first pre-diagnosis data associated with a contact failure of at least one of the first relay or the second relay based on the first voltage value and the second voltage value.

### CROSS-REFERENCE TO RELATED APPLICATION

The present application claims priority to and the benefit of Korean Patent Application No. 10-2024-0135958, filed on Oct. 7, 2024, in the Korean Intellectual Property Office, the entire disclosure of which is incorporated by reference herein.

### BACKGROUND

### 1. Field

Aspects of embodiments of the present disclosure relate to a battery management module that generates pre-diagnosis data for a relay and/or a current meter connected to a battery cell, and a battery pack including the battery management module.

### 2. Description of the Related Art

Unlike primary batteries that are not designed to be (re)charged, secondary (or rechargeable) batteries are batteries that are designed to be discharged and recharged. Low-capacity secondary batteries are used in portable, small electronic devices, such as smart phones, feature phones, notebook computers, digital cameras, and camcorders, while large-capacity secondary batteries are widely used as power sources for driving motors in hybrid vehicles and electric vehicles and for storing power (e.g., home and/or utility scale power storage). A secondary battery generally includes an electrode assembly composed of a positive electrode and a negative electrode, a case accommodating the same, and electrode terminals connected to the electrode assembly.

When secondary batteries, for example, rechargeable batteries, such as lithium-ion batteries, are repeatedly charged and discharged, the battery life may be reduced or the battery performance may be reduced, and accordingly, a battery management system may be installed in an electric vehicle to periodically monitor a battery state. A battery management system may generally be configured to monitor a voltage, a current, a temperature, and on the like of a battery, and may manage charging and discharging of the battery.

The above information disclosed in this Background section is for enhancement of understanding of the background of the present disclosure, and therefore, it may contain information that does not constitute related (or prior) art.

### SUMMARY

A battery management system may include a current meter for monitoring a current of a battery, a relay for managing charging and discharging of the battery, and the like. A problem (e.g., an error or a fault) may occur in the current meter, the relay, and the like due to an overcurrent flowing through the battery, an external environment, and the like. However, the battery management system may not be able to detect problems in the current meter, the relay, and the like.

Embodiments of the present disclosure may be directed to a battery management module, and a battery pack including the battery management module, that may detect problems (e.g., errors or faults) in a current meter, a relay, and/or the like.

These and other aspects and features of the present disclosure will be described in or will be apparent from the following description of embodiments of the present disclosure.

According to one or more embodiments of the present disclosure, a battery management module includes: at least one battery cell; a first relay connected to a first terminal of the at least one battery cell; a second relay connected to a second terminal of the at least one battery cell; and a microcontroller configured to: receive a first voltage value of a first voltage across both ends of the first relay; receive a second voltage value of a second voltage across both ends of the second relay; and generate first pre-diagnosis data associated with a contact failure of at least one of the first relay or the second relay based on the first voltage value and the second voltage value.

In an embodiment, the microcontroller may be configured to calculate a first current value of the first relay based on the first voltage value, and calculate a second current value of the second relay based on the second voltage value.

In an embodiment, to generate the first pre-diagnosis data associated with the contact failure, the microcontroller may be further configured to: calculate a first reference value indicating a correlation between the first voltage value and the second voltage value based on the first voltage value and the second voltage value; and generate the first pre-diagnosis data based on the first reference value, a 1_1^{st} threshold value, and a 1_2^{nd} threshold value.

In an embodiment, the first reference value may indicate a ratio between the first voltage value and the second voltage value.

In an embodiment, to generate the first pre-diagnosis data based on the first reference value, the 1_1^{st} threshold value, and the 1_2^{nd} threshold value, the microcontroller may be further configured to: generate the first pre-diagnosis data indicating that the first relay and the second relay are normal, in response to determining that the first reference value is greater than or equal to the 1_1^{st} threshold value and less than or equal to the 1_2^{nd} threshold value; or generate the first pre-diagnosis data indicating that at least one of the first relay or the second relay is abnormal, in response to determining that the first reference value is less than the 1_1^{st} threshold value or greater than the 1_2^{nd} threshold value.

In an embodiment, a resistance value of the first relay may be between a first minimum resistance value and a first maximum resistance value; a resistance value of the second relay may be between a second minimum resistance value and a second maximum resistance value; and the 1_1^{st} threshold value and the 1_2^{nd} threshold value may be calculated based on the first minimum resistance value, the second minimum resistance value, the first maximum resistance value, and the second maximum resistance value.

In an embodiment, a resistance value of the first relay may be between a first minimum resistance value and a first maximum resistance value, a resistance value of the second relay may be between a second minimum resistance value and a second maximum resistance value, the 1_1^{st} threshold value may be calculated based on the first maximum resistance value and the second minimum resistance value, and the 1_2^{nd} threshold value may be calculated based on the first minimum resistance value and the second maximum resistance value.

In an embodiment, the battery management module may further include a current meter connected to one of the first terminal or the second terminal of the at least one battery cell. The microcontroller may be further configured to: receive a third voltage value of a third voltage across both ends of the current meter; and generate second pre-diagnosis data associated with at least one of a contact failure of the first relay, a contact failure of the second relay, or an error of the current meter based on the first voltage value, the second voltage value, and the third voltage value.

In an embodiment, to generate the second pre-diagnosis data, the microcontroller may be further configured to: calculate a first reference value indicating a correlation between the first voltage value and the second voltage value based on the first voltage value and the second voltage value; calculate a second reference value indicating a correlation between the first voltage value and the third voltage value based on the first voltage value and the third voltage value; and generate the second pre-diagnosis data based on the first reference value, the second reference value, a 1_1^{st} threshold value, a 1_2^{nd} threshold value, a 2_1^{st} threshold value, and a 2_2^{nd} threshold value.

In an embodiment, the first reference value may indicate a ratio between the first voltage value and the second voltage value, and the second reference value may indicate a ratio between the first voltage value and the third voltage value.

In an embodiment, to generate the second pre-diagnosis data based on the first reference value, the second reference value, the 1_1^{st} threshold value, the 1_2^{nd} threshold value, the 2_1^{st} threshold value, and the 2_2^{nd} threshold value, the microcontroller may be further configured to: generate the second pre-diagnosis data indicating that the first relay and the second relay are normal, in response to determining that the first reference value is greater than or equal to the 1_1^{st} threshold value and less than or equal to the 1_2^{nd} threshold value; or generate the second pre-diagnosis data indicating that at least one of the first relay or the second relay is abnormal, in response to determining that the first reference value is less than the 1_1^{st} threshold value or greater than the 1_2^{nd} threshold value.

In an embodiment, to generate the second pre-diagnosis data indicating that the first relay and the second relay are normal, the microcontroller may be further configured to: generate the second pre-diagnosis data further indicating that the current meter is normal, in response to determining that the second reference value is greater than or equal to the 2_1^{st} threshold value and less than or equal to the 2_2^{nd} threshold value; or generate the second pre-diagnosis data further indicating that the current meter is abnormal, in response to determining that the second reference value is less than the 2_1^{st} threshold value or greater than the 2_2^{nd} threshold value.

In an embodiment, a resistance value of the first relay may be between a first minimum resistance value and a first maximum resistance value, a resistance value of the second relay may be between a second minimum resistance value and a second maximum resistance value, a resistance value of the current meter may be between a third minimum resistance value and a third maximum resistance value, the 1_1^{st} threshold value and the 1_2^{nd} threshold value may be calculated based on the first minimum resistance value, the second minimum resistance value, the first maximum resistance value, and the second maximum resistance value, and the 2_1^{st} threshold value and the 2_2^{nd} threshold value may be calculated based on the first minimum resistance value, the first maximum resistance value, the third minimum resistance value, and the third maximum resistance value.

In an embodiment, a resistance value of the first relay may be between a first minimum resistance value and a first maximum resistance value, a resistance value of the current meter may be between a third minimum resistance value and a third maximum resistance value, the 2_1^{st} threshold value may be calculated based on the first maximum resistance value and the third minimum resistance value, and the 2_2^{nd} threshold value may be calculated based on the first minimum resistance value and the third maximum resistance value.

According to one or more embodiments of the present disclosure, a battery pack includes: a battery management module including: at least one battery cell; a first relay connected to a first terminal of the at least one battery cell; a second relay connected to a second terminal of the at least one battery cell; a current meter connected to one of the first terminal or the second terminal of the at least one battery cell; and a microcontroller; and a battery management master module connected to the microcontroller of the battery management module. The microcontroller is configured to: receive a first voltage value of a first voltage across both ends of the first relay; receive a second voltage value of a second voltage across both terminals of the second relay; receive a third voltage value of a third voltage across both ends of the current meter; and generate pre-diagnosis data associated with at least one of a contact failure of the first relay, a contact failure of the second relay, or an error of the current meter based on the first voltage value, the second voltage value, and the third voltage value. The battery management master module is configured to: receive the pre-diagnosis data from the battery management module; and output a command to control the at least one battery cell based on the pre-diagnosis data.

In an embodiment, to output the command to control the at least one battery cell, the battery management master module may be further configured to: output a command to control an output of the at least one battery cell, in response to the pre-diagnosis data indicating that at least one of the first relay or the second relay is abnormal.

In an embodiment, to output the command to control the at least one battery cell, the battery management master module may be further configured to: output a command to control an output of the at least one battery cell, in response to the pre-diagnosis data indicating that the current meter is abnormal.

According to one or more embodiments of the present disclosure, a battery pack includes: a battery management module including: at least one battery cell; a first relay connected to a first terminal of the at least one battery cell; a second relay connected to a second terminal of the at least one battery cell; a current meter connected to one of the first terminal or the second terminal of the at least one battery cell; and a microcontroller; and a battery management master module connected to the microcontroller of the battery management module. The microcontroller is configured to: receive a first voltage value of a first voltage across both ends of the first relay; receive a second voltage value of a second voltage across both terminals of the second relay; receive a third voltage value of a third voltage across both ends of the current meter; and generate pre-diagnosis data associated with at least one of a contact failure of the first relay, a contact failure of the second relay, or an error of the current meter based on the first voltage value, the second voltage value, and the third voltage value. The battery management master module is configured to: receive the pre-diagnosis data from the battery management module; and output an alarm associated with at least one of the first relay, the second relay, or the current meter based on the pre-diagnosis data.

In an embodiment, to output the alarm associated with the at least one of the first relay, the second relay, or the current meter, the battery management master module may be further configured to output a first alarm signal indicating that at least one of the first relay or the second relay has a contact failure, in response to the pre-diagnosis data indicating that at least one of the first relay or the second relay is abnormal.

In an embodiment, to output the alarm associated with the at least one of the first relay, the second relay, or the current meter, the battery management master module may be further configured to output a second alarm signal indicating that the current meter has an error, in response to the pre-diagnosis data indicating that the current meter is abnormal.

According to some embodiments of the present disclosure, a user may receive information on a contact failure of a relay based on pre-diagnosis data associated with the contact failure of the relay, and may take an action, such as replacing the relay, before a safety problem related to the relay occurs.

According to some embodiments of the present disclosure, a user may receive information on an error of a current meter based on pre-diagnosis data associated with the error of the current meter, and may take an action, such as replacing the current meter, before a safety problem related to the current meter occurs.

According to some embodiments of the present disclosure, an alarm message (e.g., a first relay contact failure, a second relay contact failure, a current meter error, or the like) may be output through an output device connected to a battery pack. For example, the alarm message may be displayed on an interface device connected to the battery pack, and accordingly, a user of the battery pack may recognize the alarm message. As another example, a voice, a warning alarm, and/or the like associated with the warning message may be output through a sound wave output device connected to the battery pack, and accordingly, a user of the battery pack may recognize the alarm message. Further or as another example, an alarm signal may be transmitted to an external system of the battery pack, and accordingly, an external user may recognize the alarm message.

However, aspects and features of the present disclosure are not limited to those described above, and other aspects and features not mentioned will be clearly understood by a person skilled in the art from the detailed description, described below.

### BRIEF DESCRIPTION OF DRAWINGS

The following drawings attached to this specification illustrate embodiments of the present disclosure, and further describe aspects and features of the present disclosure together with the detailed description of the present disclosure. Thus, the present disclosure should not be construed as being limited to the drawings:

FIG. 1 is a block diagram of a configuration of a battery management system according to an embodiment of the present disclosure;

FIG. 2 is a block diagram of a battery management system according to an embodiment of the present disclosure;

FIG. 3 is a block diagram of a battery management module according to an embodiment of the present disclosure;

FIG. 4 is a flowchart illustrating an example of a pre-diagnosis method for a battery management module according to an embodiment of the present disclosure;

FIG. 5 is a flowchart illustrating an example of a process of generating first pre-diagnosis data according to an embodiment of the present disclosure;

FIG. 6 is a flowchart illustrating an example of a process of generating second pre-diagnosis data according to an embodiment of the present disclosure;

FIG. 7 is a flowchart illustrating an operation of a battery management master module that receives pre-diagnosis data according to an embodiment of the present disclosure;

FIG. 8 is a view illustrating an example of a battery pack according to an embodiment of the present disclosure;

FIG. 9 is a view illustrating an example of a battery pack according to an embodiment of the present disclosure;

FIG. 10 is a view illustrating an example of a vehicle body including a battery pack and components of the vehicle body according to an embodiment of the present disclosure; and

FIG. 11 is a view illustrating an example of a vehicle body including a battery pack and components of the vehicle body according to an embodiment of the present disclosure.

### DETAILED DESCRIPTION

Hereinafter, embodiments of the present disclosure will be described, in detail, with reference to the accompanying drawings. The terms or words used in this specification and claims should not be construed as being limited to the usual or dictionary meaning and should be interpreted as meaning and concept consistent with the technical idea of the present disclosure based on the principle that the inventor can be his/her own lexicographer to appropriately define the concept of the term to explain his/her invention in the best way.

The embodiments described in this specification and the configurations shown in the drawings are only some of the embodiments of the present disclosure and do not represent all of the technical ideas, aspects, and features of the present disclosure. Accordingly, it should be understood that there may be various equivalents and modifications that can replace or modify the embodiments described herein at the time of filing this application.

It will be understood that when an element or layer is referred to as being “on,” “connected to,” or “coupled to” another element or layer, it may be directly on, connected, or coupled to the other element or layer or one or more intervening elements or layers may also be present. When an element or layer is referred to as being “directly on,” “directly connected to,” or “directly coupled to” another element or layer, there are no intervening elements or layers present. For example, when a first element is described as being “coupled” or “connected” to a second element, the first element may be directly coupled or connected to the second element or the first element may be indirectly coupled or connected to the second element via one or more intervening elements.

In the figures, dimensions of the various elements, layers, etc. may be exaggerated for clarity of illustration. The same reference numerals designate the same elements. As used herein, the term “and/or” includes any and all combinations of one or more of the associated listed items. Further, the use of “may” when describing embodiments of the present disclosure relates to “one or more embodiments of the present disclosure.” Expressions, such as “at least one of” and “any one of,” when preceding a list of elements, modify the entire list of elements and do not modify the individual elements of the list. When phrases such as “at least one of A, B and C, “at least one of A, B or C,” “at least one selected from a group of A, B and C,” or “at least one selected from among A, B and C” are used to designate a list of elements A, B and C, the phrase may refer to any and all suitable combinations or a subset of A, B and C, such as A, B, C, A and B, A and C, B and C, or A and B and C. As used herein, the terms “use,” “using,” and “used” may be considered synonymous with the terms “utilize,” “utilizing,” and “utilized,” respectively. As used herein, the terms “substantially,” “about,” and similar terms are used as terms of approximation and not as terms of degree, and are intended to account for the inherent variations in measured or calculated values that would be recognized by those of ordinary skill in the art.

It will be understood that, although the terms first, second, third, etc. may be used herein to describe various elements, components, regions, layers, and/or sections, these elements, components, regions, layers, and/or sections should not be limited by these terms. These terms are used to distinguish one element, component, region, layer, or section from another element, component, region, layer, or section. Thus, a first element, component, region, layer, or section discussed below could be termed a second element, component, region, layer, or section without departing from the teachings of example embodiments.

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

The terminology used herein is for the purpose of describing embodiments of the present disclosure and is not intended to be limiting of the present disclosure. As used herein, the singular forms “a” and “an” are intended to include the plural forms as well, unless the context clearly indicates otherwise. It will be further understood that the terms “includes,” “including,” “comprises,” and/or “comprising,” when used in this specification, specify the presence of stated features, integers, steps, operations, elements, and/or components but do not preclude the presence or addition of one or more other features, integers, steps, operations, elements, components, and/or groups thereof.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a) and 35 U.S. C. § 132(a).

References to two compared elements, features, etc. as being “the same” may mean that they are “substantially the same”. Thus, the phrase “substantially the same” may include a case having a deviation that is considered low in the art, for example, a deviation of 5% or less. In addition, when a certain parameter is referred to as being uniform in a given region, it may mean that it is uniform in terms of an average.

Throughout the specification, unless otherwise stated, each element may be singular or plural.

Arranging an arbitrary element “above (or below)” or “on (under)” another element may mean that the arbitrary element may be disposed in contact with the upper (or lower) surface of the element, and another element may also be interposed between the element and the arbitrary element disposed on (or under) the element.

In addition, it will be understood that when a component is referred to as being “linked,” “coupled,” or “connected” to another component, the elements may be directly “coupled,” “linked” or “connected” to each other, or another component may be “interposed” between the components”.

Throughout the specification, when “A and/or B” is stated, it means A, B or A and B, unless otherwise stated. That is, “and/or” includes any or all combinations of a plurality of items enumerated. When “C to D” is stated, it means C or more and D or less, unless otherwise specified.

As used herein, the phrase “more than or equal to” may be replaced with the term “exceeding”, and the phrase “less than or equal to” may be replaced with the term “below”. As such, the term “exceeding” may be replaced with the phrase “more than or equal to”, and the term “below” may be replaced with the phrase “less than or equal to”. In other words, the meaning of these phrases and terms as used in the present disclosure is not limited by cases where the same value exists in “equal to or more than”, “equal to or less than”, “exceeding”, and “below”. In an embodiment of the present disclosure, a case where a first reference value is more than or equal to a 1_1^{st} threshold value and less than or equal to a 1_2^{nd} threshold value may be replaced with a case where the first reference value exceeds the 1_1^{st} threshold value and is below the 1_2^{nd} threshold value. In other words, a case where the first reference value is below the 1_1^{st} threshold value or exceeds the 1_2^{nd} threshold value may be replaced with a case where the first reference value is more than or equal to the 1_1^{st} threshold value or less than or equal to the 1_2^{nd} threshold value.

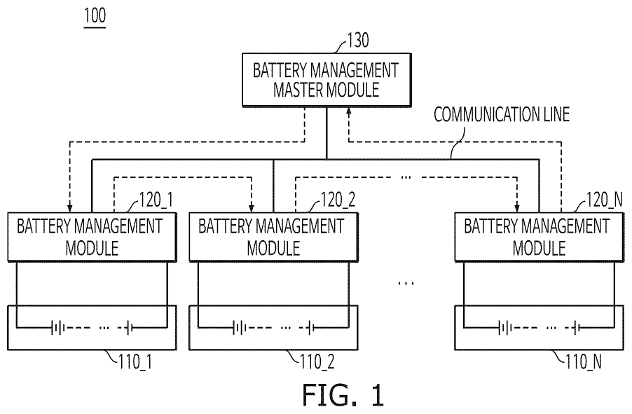

FIG. 1 is a block diagram of a configuration of a battery management system 100 according to an embodiment of the present disclosure. A battery pack may include the battery management system 100. The battery management system 100 may monitor voltages, currents, temperatures, and the like of battery cells, and may manage charging and discharging of a battery to monitor states of the battery cells.

Referring to FIG. 1, the battery management system 100 according to an embodiment of the present disclosure may include one or more battery management modules (e.g., one or more battery management circuits or controllers) 120_1, 120_2, . . . , 120_N, where N is an integer greater than 1, and a battery management master module (e.g., a battery management master circuit or controller) 130. The one or more battery management modules 120_1, 120_2, . . . , 120_N may be respectively connected to one or more battery modules 110_1, 110_2, . . . , 110_N, each including a plurality of battery cells, and may each monitor states of the battery cells in a corresponding battery module. In some embodiments, the battery management master module 130 may receive states information of the battery cells associated with the battery management modules from the one or more battery management modules 120_1, 120_2, . . . , 120_N.

In an embodiment, the battery management system 100 may receive information associated with the states of the battery cells from the one or more battery management modules 120_1, 120_2, . . . , 120_N in a daisy chain manner. For example, a battery management module (e.g., a present or current battery management module) may accumulate state information of a previous battery management module, and may transmit the accumulated state information to a next battery management module. For example, the first battery management module 120_1 may receive state information of the first battery module 110_1, and may transmit the received state information to the second battery management module 120_2. The second battery management module 120_2 may receive the state information of the first battery module 110_1 and state information of the second battery module 110_2, and may transmit the state information to a next battery management module. The Nth battery management module 120_N may transmit state information of the first battery module 110_1 to the Nth battery module 110_N to the battery management master module 130. As another example, when a subsequent battery management module receives abnormal state information from a previous battery management module, the subsequent battery management module may continuously or substantially continuously transmit the abnormal state information to the battery management master module 130. The method of transmitting the state information of a battery cell through a daisy chain method is not limited to the above-described example, and may be performed in various suitable ways.

In an embodiment, in the battery management system 100, the battery management master module 130 may directly receive information on states of the battery cells and/or information on a defect of a battery management module from the respective battery management modules 120_1, 120_2, . . . , 120_N. For example, the respective battery management modules 120_1, 120_2, . . . , 120_N may communicate with the battery management master module 130, and the respective battery management modules 120_1, 120_2, . . . , 120_N may transmit the information on the states of the corresponding battery cells and/or the information on the defect of the corresponding battery management module to the battery management master module 130. In an embodiment, the respective battery management modules 120_1, 120_2, . . . , 120_N may communicate with the battery management master module 130 through a communication line.

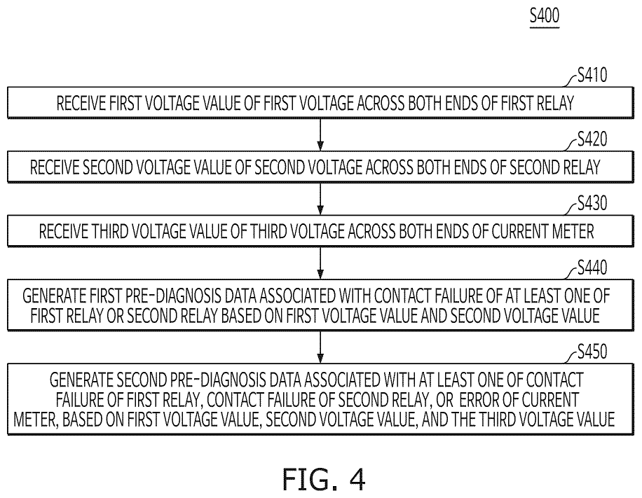

In an embodiment, the battery management modules 120_1, 120_2, . . . , 120_N may each include one or more relays and/or current meters associated with the battery modules 110_1, 110_2, . . . , 110_N. The battery management modules 120_1, 120_2, . . . , 120_N may each include a microcontroller unit (e.g., a microcontroller) that receives voltage values of the one or more relays and/or current meters. The microcontroller unit may generate pre-diagnosis data associated with a contact failure for each of the one or more relays based on the received voltage values. Additionally or as another example, the microcontroller unit may generate pre-diagnosis data associated with an error for the current meter based on the received voltage values. A process of generating, by the microcontroller, the pre-diagnosis data will be described in more detail below with reference to FIGS. 4 to 7.

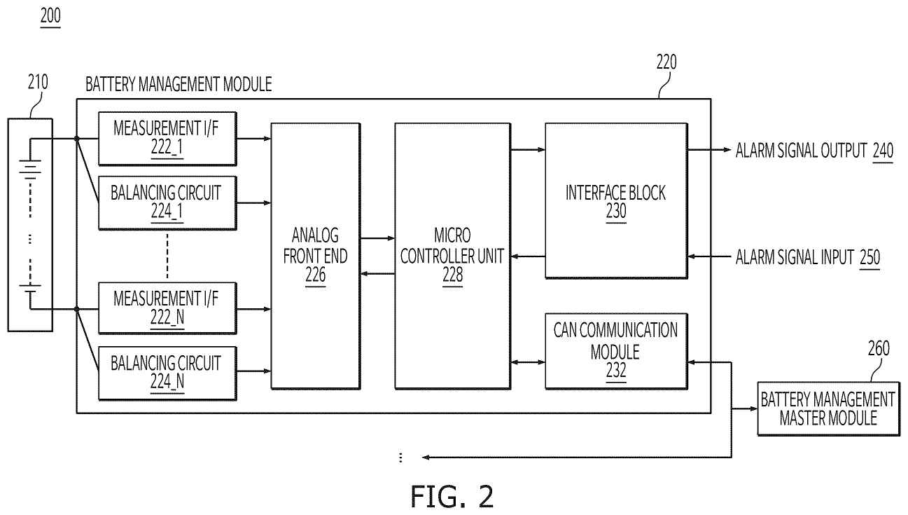

FIG. 2 is a block diagram of a battery management system 200 according to an embodiment of the present disclosure.

Referring to FIG. 2, a battery management module (e.g., a battery management circuit or controller) 220 may measure a state of a battery cell in a battery module 210, and may transmit the state to a battery management master module (e.g., a battery management master circuit or controller) 260 and/or a subsequent battery management module. For example, the battery management module 220 may receive state information of a battery cell from the battery module 210, and may transmit the state information to the battery management master module 260 and/or the subsequent battery management module. As such, the battery management module 220 may include measurement interfaces 222_1,. 222_N, balancing circuits 224_1, . . . , 224_N, an analog front end 226, a microcontroller unit (e.g., a microcontroller) 228, an interface block 230, and a CAN communication module (e.g., a CAN communication circuit) 232.

The battery management module 220 may be connected to the battery module 210 including at least one battery cell, and may monitor a state of the at least one battery cell. For example, the measurement interfaces 222_1, . . . , 222_N and the balancing circuits 224_1, . . . , 224_N may measure states of the battery cells, such as a voltage, a current, and a temperature, from the battery cells of the battery module 210.

The analog front end 226 may measure the states of the battery cells, such as a voltage, a current, and a temperature, which are analog signals, through the measurement interfaces 222_1, . . . , 222_N and the balancing circuits 224_1, . . . , 224_N, and may convert the analog signals into digital signals. For example, the analog front end 226 may receive state information of the battery cells, such as a voltage, a current, and a temperature, which are analog signals, from the measurement interfaces 222_1, . . . , 222_N and the balancing circuits 224_1, . . . , 224_N, and may convert the analog signals into digital signals. The analog front end 226 may transmit the converted digital signals to the microcontroller unit 228.

In an embodiment, at least one of the measurement interfaces 222_1, . . . , 222_N or the balancing circuits 224_1, . . . , 224_N may include a relay. The relay may be connected to the battery module 210. As the relay is opened, a power supply connected to the battery module 210 may be disconnected. For example, a power supplied to the battery module 210 may be disconnected by opening the relay. On the other hand, as the relay is closed, the power supply may be connected to the battery module 210. For example, the power may be supplied to the battery module 210 by closing the relay.

In an embodiment, at least one of the measurement interfaces 222_1, . . . , 222_N or the balancing circuits (224_1, . . . , 224_N) may include a current meter. The current meter may be connected to the battery module 210. For example, the current meter may be connected to a first terminal (e.g., a positive terminal) or a second terminal (e.g., a negative terminal) of the battery module 210 to measure a current of a point where the current meter is connected. For example, the current meter may measure a current by using a shunt resistor. As another example, the current meter may include or may be a hall sensor, a current transformer, or the like.

In an embodiment, the measurement interfaces 222_1, . . . , 222_N may measure voltages between both terminals of a relay and/or a current meter included in each of the measurement interfaces 222_1, . . . , 222_N and the balancing circuits 224_1, . . . , 224_N. The measured voltage may be converted into a digital signal by the analog front end 226, and the digital signal may be transmitted to the microcontroller unit 228.

The microcontroller unit 228 may monitor a state of a battery cell based on the state information, such as a voltage, a current, and a temperature of each battery cell received from the analog front end 226. For example, the microcontroller unit 228 may determine whether the battery cell is in an overvoltage state or in an undervoltage state based on at least one of the state information, such as a voltage, a current, or a temperature, of each battery cell. As another example, the microcontroller unit 228 may detect a voltage difference between battery cells based on at least one of the state information, such as a voltage, a current, or a temperature, of each battery cell. In some embodiments, when the microcontroller unit 228 detects a voltage difference between battery cells, the microcontroller unit 228 may adjust the voltage difference between the battery cells by using the balancing circuits 224_1, . . . , 224_N to balance the voltages between the battery cells.

In an embodiment, at least one of the measurement interfaces 222_1, . . . , 222_N or the balancing circuits 224_1, . . . , 224_N may include a first relay and a second relay. The first relay may be connected to a first terminal of the battery module 210. The second relay may be connected to a second terminal of the battery module 210. The at least one of the measurement interfaces 222_1, . . . , 222_N may measure a first voltage across both ends of the first relay and a second voltage across both ends of the second relay. The microcontroller unit 228 may receive a first voltage value and a second voltage value. The microcontroller unit 228 may generate first pre-diagnosis data associated with a contact failure of at least one of the first relay or the second relay based on the first voltage value and the second voltage value.

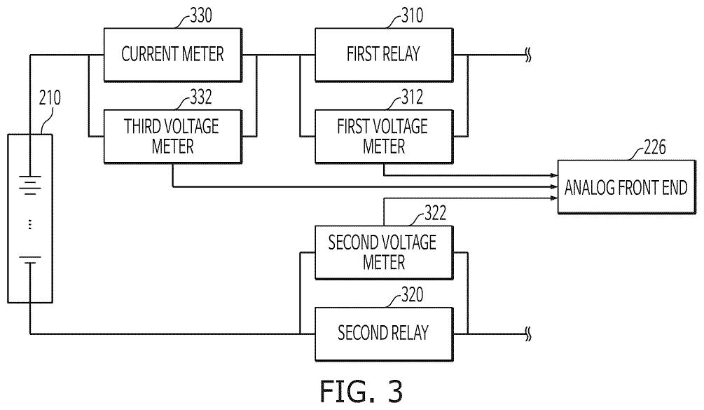

Additionally, at least one of the measurement interfaces 222_1, . . . , 222_N or the balancing circuits 224_1, . . . , 224_N may include a current meter. The current meter may be connected to the first terminal or the second terminal of the battery module 210. The at least one of the measurement interfaces 222_1, . . . , 222_N may measure a third voltage across the current meter. The microcontroller unit 228 may receive a third voltage value. The microcontroller unit 228 may generate second pre-diagnosis data associated with at least one of a contact failure of the first relay, a contact failure of the second relay, or an error of the current meter, based on the first voltage value, the second voltage value, and the third voltage value. The battery module 210, the current meter, and the relays will be described in more detail below with reference to FIG. 3.

In an embodiment, the battery management module 220 may transmit information on the states of the battery cells to the battery management master module 260 in a daisy chain manner. In more detail, the microcontroller unit 228 may receive an alarm signal input 250 output from a previous battery management module through the interface block 230. In some embodiments, the microcontroller unit 228 may transmit the state information of a corresponding battery cell to a subsequent battery management module as an alarm signal output 240 that is output through the interface block 230. The state information of the battery cell associated with the previous battery management module and the state information of the corresponding battery cell may include the accumulated state information of the battery cell for the previous battery management module connected in a daisy chain manner, but the present disclosure is not limited thereto. In some embodiments, the first battery management module and a last battery management module may be connected to the battery management master module 260.

In an embodiment, the battery management module 220 may directly transmit the state information of the battery module 210 (e.g., the state information of the battery cell or the like) and the state information of the battery management module 220 (e.g., fault information of the battery management module or the like) to the battery management master module 260. For example, the microcontroller unit 228 may transmit the state information of the battery module 210 and the state information of the battery management module 220 to the battery management master module 260 through the CAN communication module 232. In some embodiments, all battery management modules may directly communicate with the battery management master module 260 through any suitable communications (e.g., through the CAN communication module 232).

FIG. 3 is a block diagram of a battery management module according to an embodiment of the present disclosure. FIG. 3 may illustrate some of the measurement interfaces 222_1, . . . , 222_N and the balancing circuits 224_1, . . . , 224_N of the battery management module 220 illustrated in FIG. 2.

Referring to FIG. 3, a current meter 330 may be connected to a first terminal of a battery module 210 including at least one battery cell. However, the present disclosure is not limited thereto, and the current meter 330 may be connected to a second terminal of the battery module 210. In some embodiments, a first relay 310 may be connected to the first terminal of the battery module 210. A second relay 320 may be connected to the second terminal of the battery module 210.

In an embodiment, a first voltage meter 312 may measure a first voltage across both ends of the first relay 310. A second voltage meter 322 may measure a second voltage across both ends of the second relay 320. A third voltage meter 332 may measure a third voltage across both ends of the current meter 330. The measured first to third voltages may be transmitted to the analog front end 226.

In an embodiment, the microcontroller unit (e.g., the microcontroller unit 228 of FIG. 2) may calculate a first current of the first relay based on the first voltage. In more detail, the first current may be calculated as “first current=first voltage/resistance value of first relay”. Similarly, a second current may be calculated as “second current value=second voltage/resistance value of second relay”. The resistance value of the first relay and the resistance value of the second relay may be previously determined values. In an embodiment, when the resistance value of the first relay is included between a first minimum resistance value and a first maximum resistance value, the resistance value of the first relay may be one of values between the first minimum resistance value and the first maximum resistance value. For example, a resistance value of the first relay may be an average value or a median value of the first minimum resistance value and the first maximum resistance value. Similarly, when the resistance value of the second relay is included between a second minimum resistance value and a second maximum resistance value, the resistance value of the second relay may be one of values between the second minimum resistance value and the second maximum resistance value. For example, the resistance value of the second relay may be an average value or a median value between the second minimum resistance value and the second maximum resistance value.

Therefore, when a battery management module does not include the current meter 330 or when an error occurs in the current meter 330, a current of a circuit connected to the battery module 210 may be determined based on a voltage of the first relay and a voltage of the second relay.

Referring to FIG. 3, the first voltage meter 312 for measuring the voltage of the first relay 310, the second voltage meter 322 for measuring the voltage of the second relay 320, and the third voltage meter 332 for measuring the voltage of the current meter 330 are separately illustrated, but the present disclosure is not limited thereto. For example, one voltage meter may measure voltages of at least two of the first relay 310, the second relay 320, or the current meter 330.

Open or closed states of the first and second relays 310 and 320 may be controlled by the microcontroller unit and/or the battery management master module (e.g., the battery management master module 260 of FIG. 2). When the first and second relays 310 and 320 are damaged, the open or closed states of the first and second relays 310 and 320 may not be controlled. A contact failure may occur in the first and second relays 310 and 320 before the first and second relays 310 and 320 are damaged. Voltages across two terminals of each of the first and second relays 310 and 320 may be measured, and the microcontroller unit may generate pre-diagnosis data related to the contact failures of the first and second relays 310 and 320 based on the measured voltages. A user may receive information on the contact failures of the first and second relays 310 and 320 based on the pre-diagnosis data related to the contact failures of the first and second relays 310 and 320, and may take an action, such as replacing the first and second relays 310 and 320, before a safety issue regarding the first and second relays 310 and 320 occurs.

The current meter 330 may be damaged by an overcurrent or the like, and as such, an error may occur during a measurement of the current meter 330. In a comparative example, because there may be no configuration in a battery management module capable of detecting an error in the current meter 330, even when there is an error in the current measured by the current meter 330, the microcontroller unit, the battery management master module, and the like may not recognize the error in the current meter 330. In some embodiments, however, the microcontroller unit may generate pre-diagnosis data related to the error in the current meter 330 based on the voltage measured by the first, second, and third voltage meters 312, 322, and 332. Based on the pre-diagnosis data related to the error in the current meter 330, a user may receive information on the error in the current meter 330, and may take an action, such as replacing the current meter 330, before a safety issue occurs in the current meter 330.

FIG. 4 is a flowchart illustrating an example of a pre-diagnosis method S400 for a battery management module according to an embodiment of the present disclosure. The pre-diagnosis method S400 for the battery management module may be performed by the microcontroller unit (e.g., the microcontroller unit 228 of FIG. 2) included in the battery management module (e.g., the battery management module 220 of FIG. 2).

Referring to FIG. 4, the pre-diagnosis method S400 for the battery management module may start, and a first voltage value of a first voltage across both ends of a first relay may be received (S410). The first relay may be connected to a first terminal of a battery cell. Additionally, the microcontroller unit may calculate a first current value of the first relay based on the first voltage.

In an embodiment, the microcontroller unit may receive a second voltage value of a second voltage across both ends of a second relay (S420). The second relay may be connected to a second terminal of the battery cell. Additionally, the microcontroller unit may calculate a second current value of the second relay based on the second voltage value.

In an embodiment, the microcontroller unit may receive a third voltage value of a third voltage across both ends of a current meter (S430).

In an embodiment, the microcontroller unit may generate first pre-diagnosis data associated with a contact failure of at least one of the first relay or the second relay based on the first voltage value and the second voltage value (S440). In more detail, the microcontroller unit may calculate a first reference value indicating a correlation between the first voltage value and the second voltage value based on the first voltage value and the second voltage value. The first reference value may indicate a ratio between the first voltage value and the second voltage value. The microcontroller unit may generate the first pre-diagnosis data based on the calculated first reference value, a 1_1st threshold value (e.g., a 1_1st predetermined threshold value), and a 1_2nd threshold value (e.g., a 1_2nd predetermined threshold value).

In an embodiment, in response to determining that the first reference value is greater than or equal to the 1_1st threshold value and less than or equal to the 1_2nd threshold value, the microcontroller unit may generate the first pre-diagnosis data indicating that the first relay and the second relay are normal. In some embodiments, in response to determining that the first reference value is less than the 1_1st threshold value or greater than the 1_2nd threshold value, the microcontroller unit may generate the first pre-diagnosis data indicating that at least one of the first relay or the second relay is abnormal. A resistance value of the first relay may be included in the values between a first minimum resistance value and a first maximum resistance value, and a resistance value of the second relay may be included in the values between a second minimum resistance value and a second maximum resistance value. In some embodiments, the 1_1st threshold value and the 1_2nd threshold value may be calculated based on the first minimum resistance value, the second minimum resistance value, the first maximum resistance value, and the second maximum resistance value. In more detail, the 1_1st threshold value may be calculated based on the first maximum resistance value and the second minimum resistance value, and the 1_2nd threshold value may be calculated based on the first minimum resistance value and the second maximum resistance value.

In an embodiment, the microcontroller unit may generate second pre-diagnosis data associated with at least one of a contact failure of the first relay, a contact failure of the second relay, or an error of the current meter, based on the first voltage value, the second voltage value, and the third voltage value (S450). The current meter may be connected to a first terminal or a second terminal of at least one battery cell. In more detail, the microcontroller unit may calculate a first reference value indicating a correlation between the first voltage value and the second voltage value based on the first voltage value and the second voltage value. The microcontroller unit may calculate a second reference value indicating a correlation between the first voltage value and the third voltage value based on the first voltage value and the third voltage value. The microcontroller unit may generate the second pre-diagnosis data based on the calculated first reference value, the calculated second reference value, the 1_1st threshold value, the 1_2nd threshold value, a 2_1st threshold value (e.g., a 2_1st predetermined threshold value), and a 2_2nd threshold value (e.g., a 2_2nd predetermined threshold value). The first reference value may indicate a ratio between the first voltage value and the second voltage value, and the second reference value may indicate a ratio between the first voltage value and the third voltage value.

In an embodiment, in response to determining that the first reference value is greater than or equal to the 1_1st threshold value and less than or equal to the 1_2nd threshold value, the microcontroller unit may generate the second pre-diagnosis data indicating that the first relay and the second relay are normal. In some embodiments, in response to determining that the first reference value is less than the 1_1st threshold value or greater than the 1_2nd threshold value, the microcontroller unit may generate the second pre-diagnosis data indicating that at least one of the first relay or the second relay is abnormal. In addition, in response to determining that the second reference value is greater than or equal to the 2_1st threshold value and less than or equal to the 2_2nd threshold value, the microcontroller unit may generate the second pre-diagnosis data further indicating that the current meter is normal. In some embodiments, in response to determining that the second reference value is less than the 2_1st threshold value or greater than the 2_2nd threshold value, the microcontroller unit may generate the second pre-diagnosis data further indicating that the current meter is abnormal. A resistance value of the current meter may be included between a third minimum resistance value and a third maximum resistance value. The 1_1st threshold value and the 1_2nd threshold value may be calculated based on the first minimum resistance value, the second minimum resistance value, the first maximum resistance value, and the second maximum resistance value. The 2_1st threshold value and the 2_2nd threshold value may be calculated based on the first minimum resistance value, the first maximum resistance value, the third minimum resistance value, and the third maximum resistance value. For example, the 2_1st threshold value may be calculated based on the first maximum resistance value and the third minimum resistance value, and the 2_2nd threshold value may be calculated based on the first minimum resistance value and the third maximum resistance value.

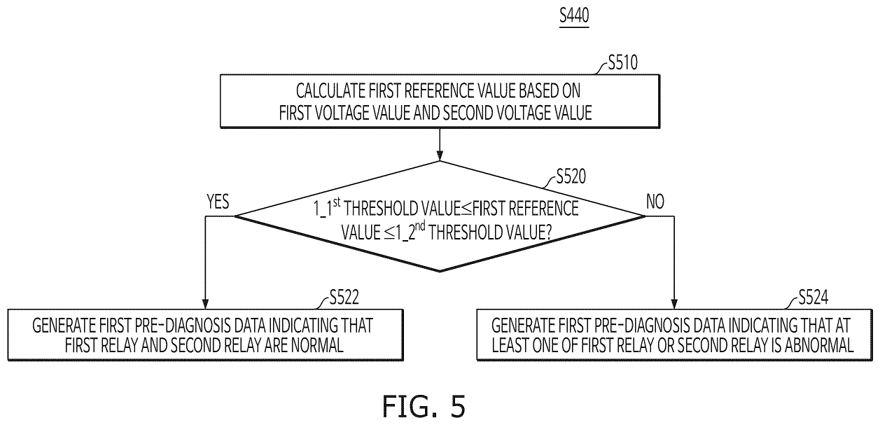

FIG. 5 is a flowchart illustrating an example of a process S440 of generating the first pre-diagnosis data according to an embodiment of the present disclosure. The microcontroller unit may generate the first pre-diagnosis data associated with a contact failure of at least one of the first relay or the second relay based on a first voltage value and a second voltage value. The process of generating the first pre-diagnosis data is described in more detail below.

Referring to FIG. 5, in an embodiment, the microcontroller unit may calculate the first reference value based on the first voltage value and the second voltage value (S510). The first reference value may represent a correlation between the first voltage value and the second voltage value. In more detail, the first reference value may represent a ratio between the first voltage value and the second voltage value. For example, the first reference value may be calculated as “first reference value=second voltage value/first voltage value”.

In an embodiment, the microcontroller unit may determine whether or not the first reference value is greater than or equal to a 1_1st threshold value (e.g., a 1_1st predetermined threshold value) and less than or equal to a 1_2nd threshold value (e.g., a 1_2nd predetermined threshold value) (S520). A resistance value of the first relay may be included between the first minimum resistance value and the first maximum resistance value. A resistance value of the second relay may be included between the second minimum resistance value and the second maximum resistance value. The 1_1st threshold value may be calculated based on the first maximum resistance value and the second minimum resistance value. The 1_2nd threshold value may be calculated based on the first minimum resistance value and the second maximum resistance value. For example, the 1_1st threshold value may be calculated as “1_1st threshold value=second minimum resistance value/first maximum resistance value”. The 1_2nd threshold value may be calculated as “1_2nd threshold value=second maximum resistance value/first minimum resistance value”.

In an embodiment, in response to determining that the first reference value is greater than or equal to the 1_1st threshold value and less than or equal to the 1_2nd threshold value (e.g., YES at S520), the microcontroller unit may generate first pre-diagnosis data indicating that the first relay and the second relay are normal (S522). On the other hand, in response to determining that the first reference value is less than the 1_1st threshold value or greater than the 1_2nd threshold value (e.g., NO at S520), the microcontroller unit may generate first pre-diagnosis data indicating that at least one of the first relay or the second relay is abnormal (S524). The microcontroller unit may transmit the first pre-diagnosis data to a battery management master module included in the battery pack.

In an embodiment, the first reference value may be calculated as “first reference value=first voltage value/second voltage value”. In some embodiments, the 1_1st threshold value may be calculated as “1_1st threshold value=first minimum resistance value/second maximum resistance value”, and the 1_2nd threshold value may be calculated as “1_2nd threshold value=first maximum resistance value/second minimum resistance value”.

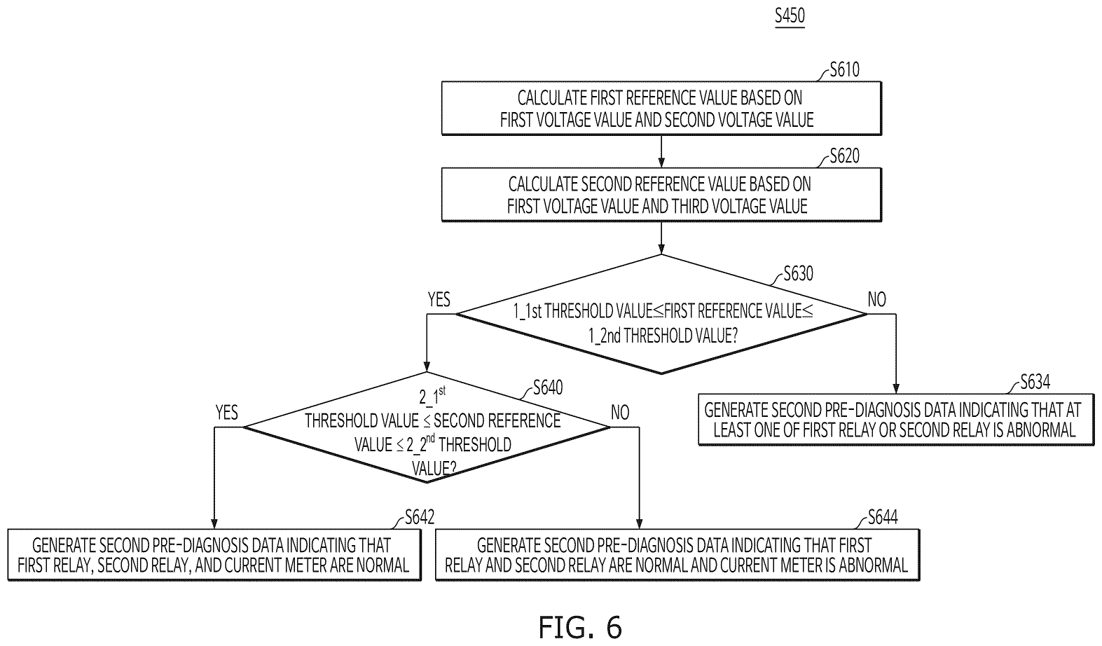

FIG. 6 is a flowchart illustrating an example of a process S450 of generating second pre-diagnosis data according to an embodiment of the present disclosure. The microcontroller unit may generate the second pre-diagnosis data associated with at least one of a contact failure of the first relay, a contact failure of the second relay, or an error of the current meter, based on a first voltage value, a second voltage value, and a third voltage value (S450). The process of generating the second pre-diagnosis data is described in more detail below.

Referring to FIG. 6, in an embodiment, the microcontroller unit may calculate a first reference value based on the first voltage value and the second voltage value (S610). The first reference value may represent a correlation between the first voltage value and the second voltage value. In more detail, the first reference value may represent a ratio between the first voltage value and the second voltage value. For example, the first reference value may be calculated as “first reference value=second voltage value/first voltage value”.

In an embodiment, the microcontroller unit may calculate a second reference value based on the first voltage value and a third voltage value (S620). The second reference value may represent a correlation between the first voltage value and the third voltage value. In more detail, the second reference value may represent a ratio between the first voltage value and the third voltage value. For example, the second reference value may be calculated as “second reference value=third voltage value/first voltage value”.

In an embodiment, the microcontroller unit may determine whether or not the first reference value is greater than or equal to a 1_1st threshold value and less than or equal to a 1_2nd threshold value (S630). A resistance value of the first relay may be included between a first minimum resistance value and a first maximum resistance value. A resistance value of the second relay may be included between a second minimum resistance value and a second maximum resistance value. The 1_1st threshold value may be calculated based on the first maximum resistance value and the second minimum resistance value. The 1_2nd threshold value may be calculated based on the first minimum resistance value and the second maximum resistance value. For example, the 1_1st threshold value may be calculated as “1_1st threshold value=second minimum resistance value/first maximum resistance value”. The 1_2nd threshold value may be calculated as “1_2nd threshold value=second maximum resistance value/first minimum resistance value”.

In an embodiment, in response to determining that the first reference value is less than the 1_1st threshold value or greater than the 1_2nd threshold value (e.g., NO at S630), the microcontroller unit may generate the second pre-diagnosis data indicating that at least one of the first relay or the second relay is abnormal (S634). The second pre-diagnosis data may not indicate whether or not a current meter is normal or abnormal. Thereafter, the microcontroller unit may transmit the second pre-diagnosis data to a battery management master module included in the battery pack.

On the other hand, in response to determining that the first reference value is greater than or equal to the 1_1st threshold value and less than or equal to the 1_2nd threshold value (e.g., YES at S630), the microcontroller unit may determine whether or not the second reference value is greater than or equal to the 2_1st threshold value and less than or equal to the 2_2nd threshold value (S640). A resistance value of the current meter may be included between a third minimum resistance value and a third maximum resistance value. The 2_1st threshold value may be calculated based on the first maximum resistance value and the third minimum resistance value. The 2_2nd threshold value may be calculated based on the first minimum resistance value and the third maximum resistance value. For example, the 2_1 threshold value may be calculated as “2_1st threshold value=third minimum resistance value/first maximum resistance value”. The 2_2nd threshold value may be calculated as “2_2nd threshold value=third maximum resistance value/first minimum resistance value”.

Additionally, in response to determining that the second reference value is greater than or equal to the 2_1st threshold value and less than or equal to the 2_2nd threshold value (e.g., YES at S640), the microcontroller unit may generate the second pre-diagnosis data further indicating that the current meter is normal (S642). In other words, the second pre-diagnosis data may indicate that the first relay, the second relay, and the current meter are normal. In an embodiment, the second reference value may be calculated as “second reference value=third voltage value/second voltage value”. In some embodiments, the 2_1st threshold value may be calculated as “2_1st threshold value=third minimum resistance value/second maximum resistance value”. The 2_2nd threshold value may be calculated as “2_2nd threshold value=third maximum resistance value/second minimum resistance value”. On the other hand, in response to determining that the second reference value is less than the 2_1st threshold value or greater than the 2_2nd threshold value (e.g., NO at S640), the microcontroller unit may generate the second pre-diagnosis data further indicating that the current meter is abnormal (S644). In other words, the second pre-diagnosis data may indicate that the first relay and the second relay are normal, and the current meter is abnormal.

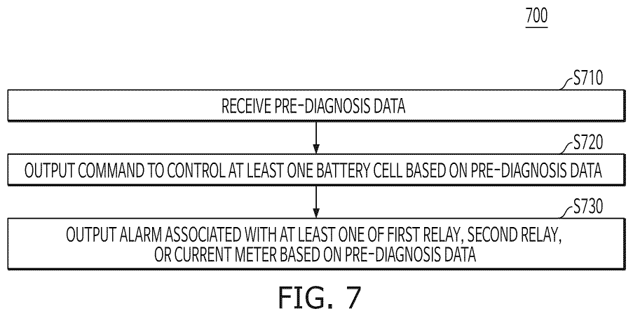

FIG. 7 is a flowchart 700 illustrating an operation of a battery management master module that receives pre-diagnosis data according to an embodiment of the present disclosure.

A battery pack may include a battery management module (e.g., a battery management circuit or controller) including at least one battery cell, a first relay connected to a first terminal of the at least one battery cell, a second relay connected to a second terminal of the at least one battery cell, a current meter connected to the first terminal or the second terminal of the at least one battery cell, and a microcontroller unit (e.g., a microcontroller) that receives a first voltage value of a first voltage across both ends of the first relay, a second voltage value of a second voltage across both ends of the second relay, and a third voltage value of a third voltage across both ends of the current meter. A battery management master module (e.g., a battery management master circuit or controller) may be connected to the microcontroller unit included in the battery management module.

Referring to FIG. 7, the battery management master module may receive pre-diagnosis data (e.g., at least one of the first pre-diagnosis data or the second pre-diagnosis data) (S710). The first pre-diagnosis data may indicate that the first relay and the second relay are normal. As another example, the first pre-diagnosis data may indicate that at least one of the first relay or the second relay is abnormal. The second pre-diagnosis data may indicate that the first relay, the second relay, and the current meter are normal. As another example, the second pre-diagnosis data may indicate that the first relay and the second relay are normal, and the current meter is abnormal. As another example, the second pre-diagnosis data may indicate that at least one of the first relay or the second relay is abnormal.

In an embodiment, the battery management master module may output a command to control at least one battery cell based on the pre-diagnosis data (S720). In more detail, the battery management master module may output a command to control at least one battery cell connected to the first relay in response to the pre-diagnosis data indicating that the first relay is abnormal. For example, the battery management master module may output a command to discharge at least one battery cell through a balancing circuit connected to the at least one battery cell. As another example, the battery management master module may output a command to disconnect the power connected to the at least one battery cell through another relay, a fuse, or the like connected to the at least one battery cell. Similarly, the battery management master module may output a command to control at least one battery cell connected to the second relay in response to the pre-diagnosis data indicating that the second relay is abnormal.

Additionally or as another example, the battery management master module may output a command to control an output of at least one battery cell in response to the pre-diagnosis data indicating that the current meter is abnormal. The battery management master module may output a command to discharge at least one battery cell through a balancing circuit connected to the at least one battery cell. As another example, the battery management master module may output a command to disconnect the power connected to the at least one battery cell through another relay, fuse, or the like connected to the at least one battery cell.

In an embodiment, the battery management master module may output an alarm associated with at least one of the first relay, the second relay, or the current meter based on the pre-diagnosis data (S730). In more detail, in response to the pre-diagnosis data indicating that at least one of the first relay or the second relay is abnormal, the battery management master module may output a first alarm signal indicating that at least one of the first relay or the second relay has a contact failure. Similarly, in response to the pre-diagnosis data indicating that the current meter is abnormal, the battery management master module may output a second alarm signal indicating that the current meter has a fault.

In an embodiment, the alarm signal (e.g., the first alarm signal or the second alarm signal) may be transmitted to the other components inside the battery pack, other components outside the battery pack, a system, and/or the like. For example, the alarm content (e.g., a first relay contact failure, a second relay contact failure, or a current meter error) may be output through an output device connected to the battery pack. For example, an alarm message may be displayed on an interface device connected to the battery pack, such that a user of the battery pack may recognize the alarm message. As another example, a sound output device connected to the battery pack may output a voice, a warning alarm, and/or the like related to the alarm content, such that a user of the battery pack may recognize the alarm content. Additionally or as another example, the alarm signal may be transmitted to an external system of the battery pack, such that an external user may recognize the alarm content.

The flowcharts of FIGS. 4 to 7, and the related descriptions above, are provided as examples of some embodiments of the present disclosure, but the present disclosure is not limited thereto. For example, one or more processes of the flowcharts and the related description above may be added/changed/removed, the order of one or more processes may be changed, and/or one or more processes may be performed concurrently (e.g., simultaneously or substantially simultaneously) with each other.

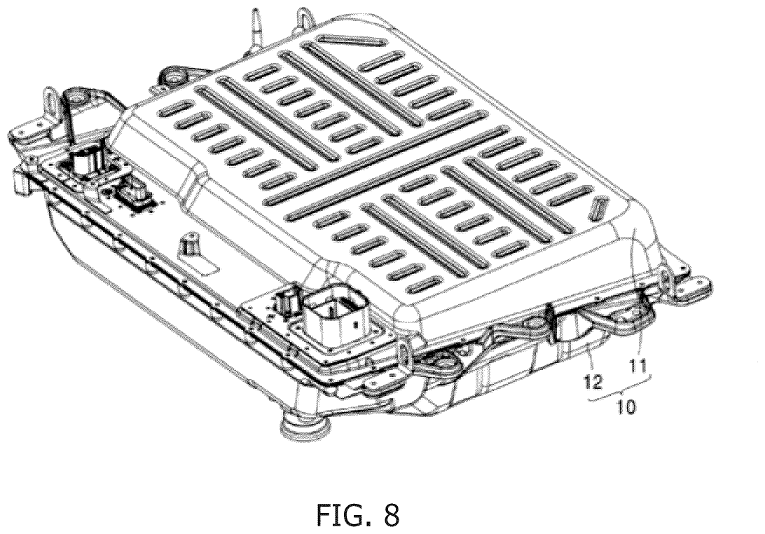

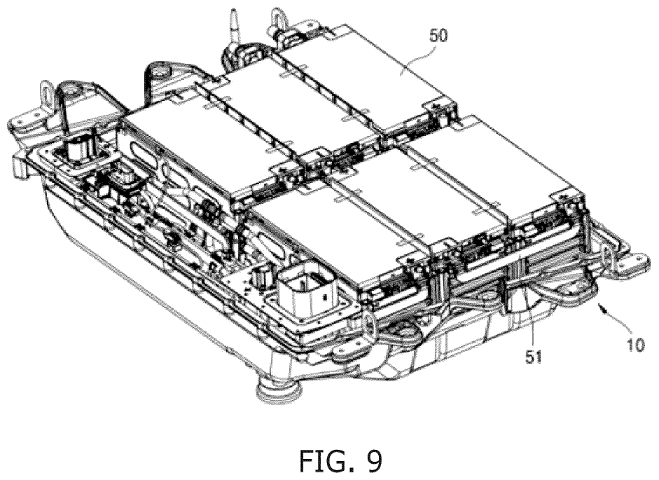

FIG. 8 is a view illustrating an example of a battery pack according to an embodiment of the present disclosure. FIG. 9 is a view illustrating an example of the battery pack according to an embodiment of the present disclosure.

Referring to FIGS. 8 and 9, the battery pack may include a plurality of battery modules 50, and a housing 10 for accommodating the plurality of battery modules 50. For example, the housing 10 may include a first housing 11 and a second housing 12 that are coupled to each other in a direction facing each other by interposing the plurality of battery modules 50 therebetween. The plurality of battery modules 50 may be electrically connected to each other by a bus bar 51, and the plurality of battery modules 50 may be electrically connected to each other in series, in parallel, or in a series-parallel hybrid manner to obtain a desired electrical output. In some embodiments, the battery pack may include the battery management system (e.g., see 100 of FIG. 1) described above with reference to FIGS. 1 to 3 to monitor a voltage, a current, a temperature, and the like of a battery cell for monitoring states of the battery cell, and to manage charging and discharging of a battery. The battery management system may include a microcontroller unit (e.g., a microcontroller) that generates pre-diagnosis data associated with at least one of a contact failure of a relay connected to at least one battery cell included in the battery module or an error of a current meter.

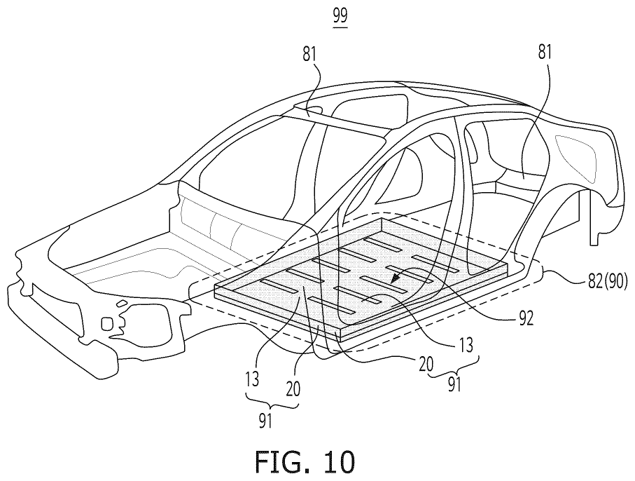

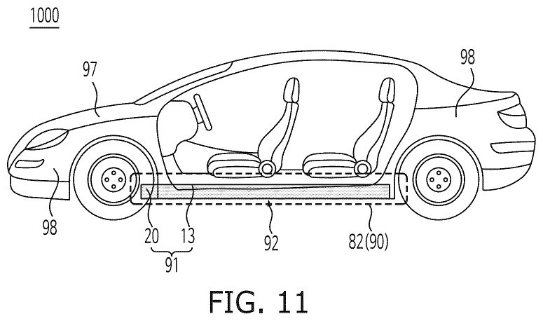

FIG. 10 is a view illustrating an example of a vehicle body including a battery pack and components of the vehicle body according to an embodiment of the present disclosure. FIG. 11 is a view illustrating an example of the vehicle body including the battery pack and the components of the vehicle body according to an embodiment of the present disclosure.

Referring to FIG. 10, a battery pack 91 may include a battery pack cover 13, which is a part of a vehicle underbody 92, and a pack frame 20 arranged on a lower portion of the vehicle underbody 92. The vehicle underbody 92 separates the inside and the outside of a vehicle from each other, and the pack frame 20 may be arranged on the outside of the vehicle. The pack frame 20 and the battery pack cover 13 may be a structure that is formed integrally with a vehicle floor 82. The pack frame 20 may refer to a housing for accommodating a battery module in a battery pack.

FIG. 11 is a schematic side view of the vehicle according to an embodiment of the present disclosure. The vehicle 1000 may be formed by combining a vehicle body 90 with additional components, such as a hood 97 at the front of the vehicle 1000, and fenders 98 arranged at the front and a rear of the vehicle 1000, respectively. The vehicle 1000 may further include a vehicle floor 82, which is one of the vehicle body components 90 including a battery pack 91 including a pack frame 20 and a battery pack cover 13.

The electronic or electric devices and/or any other relevant devices or components according to embodiments of the present disclosure described herein (e.g., the battery management master module, each of the battery management modules, the measurement interfaces, the balancing circuits, the analog front end, the microcontroller unit, and the like) may be implemented utilizing any suitable hardware, firmware (e.g. an application-specific integrated circuit), software, or a combination of software, firmware, and hardware. For example, the various components of these devices may be formed on one integrated circuit (IC) chip or on separate IC chips. Further, the various components of these devices may be implemented on a flexible printed circuit film, a tape carrier package (TCP), a printed circuit board (PCB), or formed on one substrate. Further, the various components of these devices may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the spirit and scope of the example embodiments of the present disclosure.

Although the present disclosure has been described above with respect to embodiments thereof, the present disclosure is not limited thereto. Various modifications and variations can be made thereto by those skilled in the art within the spirit of the present disclosure and the equivalent scope of the appended claims.

### REFERENCE SIGNS LIST

100: battery management system
110_1, 110_2, . . . , 110_N: battery module
120_1, 120_2, . . . , 120_N: battery management module
130: battery management master module

What is claimed is:

1. A battery management module comprising:
at least one battery cell;
a first relay connected to a first terminal of the at least one battery cell;
a second relay connected to a second terminal of the at least one battery cell; and
a microcontroller configured to:
receive a first voltage value of a first voltage across both ends of the first relay;
receive a second voltage value of a second voltage across both ends of the second relay; and
generate first pre-diagnosis data associated with a contact failure of at least one of the first relay or the second relay based on the first voltage value and the second voltage value.

2. The battery management module as claimed in claim 1, wherein the microcontroller is configured to calculate a first current value of the first relay based on the first voltage value, and calculate a second current value of the second relay based on the second voltage value.

3. The battery management module as claimed in claim 1, wherein to generate the first pre-diagnosis data associated with the contact failure, the microcontroller is further configured to:
calculate a first reference value indicating a correlation between the first voltage value and the second voltage value based on the first voltage value and the second voltage value; and
generate the first pre-diagnosis data based on the first reference value, a 1_1^{st} threshold value, and a 1_2^{nd} threshold value.

4. The battery management module as claimed in claim 3, wherein the first reference value indicates a ratio between the first voltage value and the second voltage value.

5. The battery management module as claimed in claim 3, wherein to generate the first pre-diagnosis data based on the first reference value, the 1_1^{st} threshold value, and the 1_2^{nd} threshold value, the microcontroller is further configured to:
generate the first pre-diagnosis data indicating that the first relay and the second relay are normal, in response to determining that the first reference value is greater than or equal to the 1_1^{st} threshold value and less than or equal to the 1_2^{nd} threshold value; or
generate the first pre-diagnosis data indicating that at least one of the first relay or the second relay is abnormal, in response to determining that the first reference value is less than the 1_1^{st} threshold value or greater than the 1_2^{nd} threshold value.

6. The battery management module as claimed in claim 5, wherein:
a resistance value of the first relay is between a first minimum resistance value and a first maximum resistance value;
a resistance value of the second relay is between a second minimum resistance value and a second maximum resistance value; and
the 1_1^{st} threshold value and the 1_2^{nd} threshold value are calculated based on the first minimum resistance value, the second minimum resistance value, the first maximum resistance value, and the second maximum resistance value.

7. The battery management module as claimed in claim 5, wherein a resistance value of the first relay is between a first minimum resistance value and a first maximum resistance value,
wherein a resistance value of the second relay is between a second minimum resistance value and a second maximum resistance value,
wherein the 1_1^{st} threshold value is calculated based on the first maximum resistance value and the second minimum resistance value, and
wherein the 1_2^{nd} threshold value is calculated based on the first minimum resistance value and the second maximum resistance value.

8. The battery management module as claimed in claim 1, further comprising:
a current meter connected to one of the first terminal or the second terminal of the at least one battery cell,
wherein the microcontroller is further configured to:
receive a third voltage value of a third voltage across both ends of the current meter; and
generate second pre-diagnosis data associated with at least one of a contact failure of the first relay, a contact failure of the second relay, or an error of the current meter based on the first voltage value, the second voltage value, and the third voltage value.

9. The battery management module as claimed in claim 8, wherein to generate the second pre-diagnosis data, the microcontroller is further configured to:
calculate a first reference value indicating a correlation between the first voltage value and the second voltage value based on the first voltage value and the second voltage value;
calculate a second reference value indicating a correlation between the first voltage value and the third voltage value based on the first voltage value and the third voltage value; and
generate the second pre-diagnosis data based on the first reference value, the second reference value, a 1_1^{st} threshold value, a 1_2^{nd} threshold value, a 2_1^{st} threshold value, and a 2_2^{nd} threshold value.

10. The battery management module as claimed in claim 9, wherein the first reference value indicates a ratio between the first voltage value and the second voltage value, and
wherein the second reference value indicates a ratio between the first voltage value and the third voltage value.

11. The battery management module as claimed in claim 9, wherein to generate the second pre-diagnosis data based on the first reference value, the second reference value, the 1_1^{st} threshold value, the 1_2^{nd} threshold value, the 2_1^{st} threshold value, and the 2_2^{nd} threshold value, the microcontroller is further configured to:
generate the second pre-diagnosis data indicating that the first relay and the second relay are normal, in response to determining that the first reference value is greater than or equal to the 1_1^{st} threshold value and less than or equal to the 1_2^{nd} threshold value; or
generate the second pre-diagnosis data indicating that at least one of the first relay or the second relay is abnormal, in response to determining that the first reference value is less than the 1_1^{st} threshold value or greater than the 1_2^{nd} threshold value.

12. The battery management module as claimed in claim 11, wherein to generate the second pre-diagnosis data indicating that the first relay and the second relay are normal, the microcontroller is further configured to:
generate the second pre-diagnosis data further indicating that the current meter is normal, in response to determining that the second reference value is greater than or equal to the 2_1^{st} threshold value and less than or equal to the 2_2^{nd} threshold value; or
generate the second pre-diagnosis data further indicating that the current meter is abnormal, in response to determining that the second reference value is less than the 2_1^{st} threshold value or greater than the 2_2^{nd} threshold value.

13. The battery management module as claimed in claim 12, wherein a resistance value of the first relay is between a first minimum resistance value and a first maximum resistance value,
wherein a resistance value of the second relay is between a second minimum resistance value and a second maximum resistance value,
wherein a resistance value of the current meter is between a third minimum resistance value and a third maximum resistance value,
wherein the 1_1^{st} threshold value and the 1_2^{nd} threshold value are calculated based on the first minimum resistance value, the second minimum resistance value, the first maximum resistance value, and the second maximum resistance value, and
wherein the 2_1^{st} threshold value and the 2_2^{nd} threshold value are calculated based on the first minimum resistance value, the first maximum resistance value, the third minimum resistance value, and the third maximum resistance value.

14. The battery management module as claimed in claim 12, wherein a resistance value of the first relay is between a first minimum resistance value and a first maximum resistance value,
wherein a resistance value of the current meter is between a third minimum resistance value and a third maximum resistance value,
wherein the 2_1^{st} threshold value is calculated based on the first maximum resistance value and the third minimum resistance value, and
wherein the 2_2^{nd} threshold value is calculated based on the first minimum resistance value and the third maximum resistance value.

15. A battery pack comprising:
a battery management module comprising:
at least one battery cell;
a first relay connected to a first terminal of the at least one battery cell;
a second relay connected to a second terminal of the at least one battery cell;
a current meter connected to one of the first terminal or the second terminal of the at least one battery cell; and
a microcontroller; and
a battery management master module connected to the microcontroller of the battery management module,
wherein the microcontroller is configured to:
receive a first voltage value of a first voltage across both ends of the first relay;
receive a second voltage value of a second voltage across both terminals of the second relay;
receive a third voltage value of a third voltage across both ends of the current meter; and
generate pre-diagnosis data associated with at least one of a contact failure of the first relay, a contact failure of the second relay, or an error of the current meter based on the first voltage value, the second voltage value, and the third voltage value, and
wherein the battery management master module is configured to:
receive the pre-diagnosis data from the battery management module; and
output a command to control the at least one battery cell based on the pre-diagnosis data.

16. The battery pack as claimed in claim 15, wherein to output the command to control the at least one battery cell, the battery management master module is further configured to:
output a command to control an output of the at least one battery cell, in response to the pre-diagnosis data indicating that at least one of the first relay or the second relay is abnormal.

17. The battery pack as claimed in claim 15, wherein to output the command to control the at least one battery cell, the battery management master module is further configured to:
output a command to control an output of the at least one battery cell, in response to the pre-diagnosis data indicating that the current meter is abnormal.

18. A battery pack comprising:
a battery management module comprising:
at least one battery cell;
a first relay connected to a first terminal of the at least one battery cell;
a second relay connected to a second terminal of the at least one battery cell;
a current meter connected to one of the first terminal or the second terminal of the at least one battery cell; and
a microcontroller; and
a battery management master module connected to the microcontroller of the battery management module,
wherein the microcontroller is configured to:
receive a first voltage value of a first voltage across both ends of the first relay;
receive a second voltage value of a second voltage across both terminals of the second relay;
receive a third voltage value of a third voltage across both ends of the current meter; and
generate pre-diagnosis data associated with at least one of a contact failure of the first relay, a contact failure of the second relay, or an error of the current meter based on the first voltage value, the second voltage value, and the third voltage value, and
wherein the battery management master module is configured to:
receive the pre-diagnosis data from the battery management module; and
output an alarm associated with at least one of the first relay, the second relay, or the current meter based on the pre-diagnosis data.

19. The battery pack as claimed in claim 18, wherein to output the alarm associated with the at least one of the first relay, the second relay, or the current meter, the battery management master module is further configured to output a first alarm signal indicating that at least one of the first relay or the second relay has a contact failure, in response to the pre-diagnosis data indicating that at least one of the first relay or the second relay is abnormal.

20. The battery pack as claimed in claim 18, wherein to output the alarm associated with the at least one of the first relay, the second relay, or the current meter, the battery management master module is further configured to output a second alarm signal indicating that the current meter has an error, in response to the pre-diagnosis data indicating that the current meter is abnormal.
